(19) United States
(12) Patent Application Publication
(10) Pub. No.: US 2009/0166816 A1
(43) Pub. Date: Jul. 2, 2009

(54) SEMICONDUCTOR DEVICE AND METHOD OF FABRICATING THE SAME

(76) Inventor: Hee-Dae Kim, Bucheon-si (KR)

Correspondence Address: SHERR & VAUGHN, PLLC, 620 HERNDON PARKWAY, SUITE 200, HERNDON, VA, 20170, US

(21) Appl. No.: 12/344,560

(22) Filed: Dec. 28, 2008

(30) Foreign Application Priority Data
Dec. 28, 2007 (KR) 10-2007-0139978

(51) Int. Cl. H01L 23/58; H01L 21/31

(52) U.S. Cl. 257/641; 438/763; 257/E21.24; 257/E23.142; 257/E23.194

(57) ABSTRACT

A method of fabricating a semiconductor device may include: forming an oxide film pattern and a poly film pattern over a semiconductor substrate to expose a portion of the surface of the semiconductor substrate; and then forming a spacer composed of a first insulating material on sidewalls of the oxide film pattern and the poly film pattern; and then forming a second insulating film over the semiconductor substrate including the spacer and the poly film, the second insulating film having a first portion formed over the exposed portion of the semiconductor substrate, a second portion formed over the poly film pattern and a third portion formed at an incline between the first and second portions.

The present application claims priority under 35 U.S.C. 119 to Korean Patent Application No. 10-2007-0139978 (filed on Dec. 28, 2007), which is hereby incorporated by reference in its entirety.

### BACKGROUND

In general, as semiconductor devices are highly integrated, the aspect ratio of contact holes is increased and the size of the contact holes is reduced. As a result the probability that metal atoms reach the insides of the contact holes by a sputtering process is reduced. Therefore, the step coverage of metal lines is lowered and a contact process through the contact holes becomes difficult.

One approach to address this issue involves forming plugs made of a metal, such as tungsten or polycrystalline silicon, in advance in the contact holes to lower a contact resistance. Metal lines connected to the metal plugs are then formed. In this approach, in order to increase the operation speed of a semiconductor device, tungsten having a low resistivity is mainly used. As part of this approach, a metal, such as tungsten is deposited on the entire surface of the semiconductor device by CVD in order to fill the insides of contact hole regions, and then the deposited tungsten in unnecessary regions is removed by an etch-back process in order to fill only the insides of contact holes, thereby forming tungsten plugs in the contact holes.

However, the deposited tungsten in a portion having a step of a borophosphor silicate glass (BPSG) film, particularly a steeply slanting portion of the BPSG film due to a step of an electrostatic discharge (ESD) poly film, may not be completely removed by the etch-back process. The tungsten residue may cause a short between a source terminal and a gate terminal, and, thus, a defective device is fabricated.

### SUMMARY

Embodiments relate to a semiconductor device which prevents tungsten residue generated in an etch-back process and a method of fabricating the semiconductor device.

Embodiments relate to a method of fabricating a semiconductor device that may include at least one of the following: sequentially forming a buffer oxide film and an ESD poly film on and/or over a semiconductor substrate; selectively etching the buffer oxide film and the ESD poly film; forming a nitride film on and/or over the entire surface of the semiconductor substrate; forming a side wall spacer on and/or over the side walls of the buffer oxide film and the ESD poly film by etching the nitride film; and forming a BPSG film on and/or over the entire surface of the semiconductor substrate.

Embodiments relate to a method of fabricating a semiconductor device that may include at least one of the following: forming a buffer oxide film and an ESD poly film sequentially on and/or over a designated portion of a semiconductor substrate; forming a side wall spacer on and/or over the side walls of the buffer oxide film and the ESD poly film; and forming a BPSG film on and/or over the entire surface of the semiconductor substrate.

Embodiments relate to a method that may include at least one of the following: forming an oxide film over and contacting a semiconductor substrate; and then forming a poly film over and contacting the oxide film; and then forming an oxide film pattern and a poly film pattern by etching the oxide film and the poly film to expose a portion of the surface of the semiconductor substrate; and then forming a first insulating film over and contacting the exposed portion of the semiconductor substrate and the poly film pattern; and then forming a spacer on sidewalls of the oxide film and the poly film by etching the insulating film; and then forming a second insulating film over the semiconductor substrate including the spacer and the poly film, the second insulating film having a first portion formed over the exposed portion of the semiconductor substrate, a second portion formed over the poly film pattern and a third portion formed at an incline between the first and second portions.

### DRAWINGS

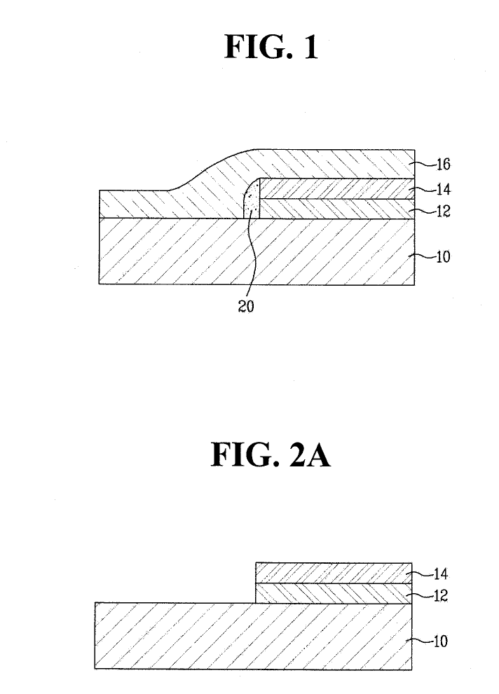

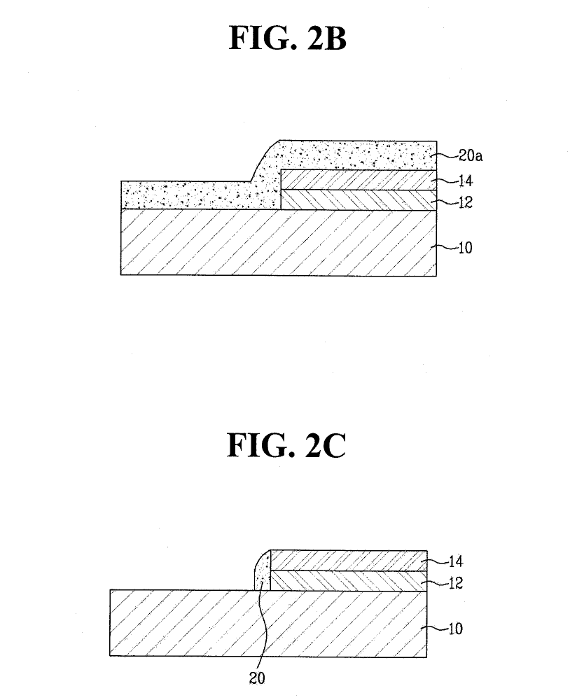

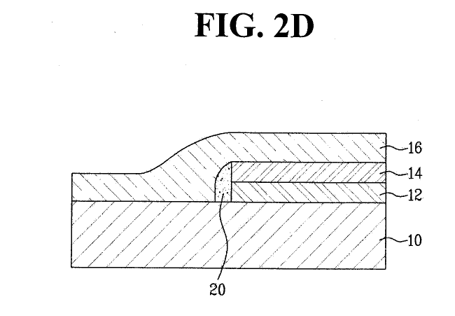

Example FIGS. 1 to 2 illustrates a semiconductor device and a method of fabricating a semiconductor device in accordance with embodiments.

### DESCRIPTION

Example FIG. 1 is a longitudinal-sectional view of a semiconductor device in accordance with embodiments. As shown in example FIG. 1, a semiconductor device includes a semiconductor substrate 10, a buffer oxide film 12 formed in a designated region of the semiconductor substrate 10, an electrostatic discharge (ESD) poly film 14 formed on, or over, the buffer oxide film, a BPSG film 16 formed on and/or over, the entire surface of the semiconductor substrate 10 including the buffer oxide film 12 and the ESD poly film 14, and a side wall spacer 20 formed on and/or over the side walls of the buffer oxide film 12 and the ESD poly film 14. According to embodiments, the side wall spacer 20 may be made from a number of materials such as, for example, a nitride film.

Example FIGS. 2A to 2D are longitudinal-sectional views illustrating a process of fabricating a semiconductor device in accordance with embodiments. First, as shown in example FIG. 2A, the buffer oxide film 12 and the ESD poly film 14 may be formed on and/or over the entire surface of the semiconductor substrate 10, and then a designated portion of each of the buffer oxide film 12 and the ESD poly film 14 may be selectively etched using a photoresist pattern exposing the designated portion of the surface of the semiconductor substrate 10 as a mask.

Thereafter, as shown in example FIG. 2B, a nitride film 20a may be deposited on and/or over substantially the entire surface of the semiconductor substrate 10 including the buffer oxide film 12 and the ESD poly film 14. The nitride film 20a may vary in thickness may, for example, have a thickness of about 3,000 to about 4,000 Å.

As shown in example FIG. 2C, the side wall spacer 20 may then be formed on and/or over the side walls of the buffer oxide film 12 and the ESD poly film 14 by etching the nitride film 20a such as, for example, by a dry etching method. Thereafter, as shown in example FIG. 2D, the BPSG film 16 may be formed on and/or over the entire surface of the semiconductor substrate 10. The side wall spacer 20 tends to reduce the slope of the BPSG film 16, thus preventing the generation of tungsten residue on a steeply slanting portion of the BPSG film 16. At this stage the structure shown in example FIG. 2D may be subjected to subsequent processing steps in order to form a wide variety of semiconductor devices.

The slope of the BPSG film 16 can be varied by controlling the thickness of the nitride film 20a, controlling the amount of etching that is applied to the nitride film 20a, and controlling the thickness of the BPSG film 16. As described above, the semiconductor device and the method of fabricating the same in accordance with embodiments allow an interlayer insulating film to have a gentle slant, and thus prevent residue such as, for example, tungsten residue from being generated in an etch-back process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially forming a buffer oxide film and a poly film over a semiconductor substrate;
and then
selectively etching the buffer oxide film and the poly film; and then
forming a nitride film over the semiconductor substrate; and then
forming a spacer on sidewalls of the buffer oxide film and the poly film by etching the nitride film; and then
forming an interlayer insulating film over the semiconductor substrate including the spacer and the poly film.

2. The method of claim 1, wherein forming the nitride film comprises forming the nitride film over substantially an entire surface of the semiconductor substrate.

3. The method of claim 1, wherein the interlayer insulating film comprises a borophosphor silicate glass film.

4. The method of claim 1, wherein the poly film comprises an electrostatic discharge poly film.

5. The method of claim 1, wherein the nitride film has a thickness in a range between approximately 3,000 to 4,000 Å.

6. The method of claim 1, wherein etching the nitride film comprises a dry etching method.

7. The method of claim 1, wherein a portion of the interlayer insulating film formed over the spacer is inclined.

8. A method comprising:
forming an oxide film over and contacting a semiconductor substrate; and then
forming a poly film over and contacting the oxide film; and then
forming an oxide film pattern and a poly film pattern by etching the oxide film and the poly film to expose a portion of the surface of the semiconductor substrate; and then
forming a first insulating film over and contacting the exposed portion of the semiconductor substrate and the poly film pattern; and then
forming a spacer on sidewalls of the oxide film pattern and the poly film pattern by etching the insulating film; and then
forming a second insulating film over the semiconductor substrate including the spacer and the poly film pattern, the second insulating film having a first portion formed over the exposed portion of the semiconductor substrate, a second portion formed over the poly film pattern and a third portion formed at an incline between the first and second portions.

9. The method of claim 8, wherein the first insulating film comprises a nitride film.

10. The method of claim 9, wherein the nitride film has a thickness in a range between approximately 3,000 to 4,000 Å.

11. The method of claim 8, wherein the first insulating film has a thickness in a range between approximately 3,000 to 4,000 Å.

12. The method of claim 8, wherein the second insulating film comprises a borophosphor silicate glass film.

13. The method of claim 8, wherein the first insulating film comprises a nitride film and the second insulating film comprises a borophosphor silicate glass film.

14. The method of claim 8, wherein the poly film comprises an electrostatic discharge poly film.

15. The method of claim 8, wherein the first insulating film is etched using a dry etching method.

16. A device comprises:
a buffer oxide film and a poly film sequentially formed over a semiconductor substrate;
a spacer formed on sidewalls of the buffer oxide film and the poly film; and
an interlayer insulating film formed over the semiconductor substrate.

17. The device of claim 16, wherein the interlayer insulating film includes a borophosphor silicate glass film.

18. The device of claim 16, wherein the poly film comprises an electrostatic discharge poly film.

19. The device of claim 6, wherein the spacer comprises a nitride film.

20. The device of claim 16, wherein a portion of the interlayer insulating film formed over the spacer is inclined.
